(19) United States
(12) Patent Application Publication
(10) Pub. No.: US 2017/0243833 A1
(43) Pub. Date: Aug. 24, 2017

(54) PACKAGE MODULE AND METHOD OF MANUFACTURING THE SAME

(71) Applicant: Samsung Electro-Mechanics Co., Ltd., Suwon-si (KR)

(72) Inventors: Jong Woo CHOI, Suwon-si (KR); Hyun Kook CHO, Suwon-si (KR); Il Hyeong LEE, Suwon-si (KR); Seung Yong CHOI, Suwon-si (KR)

(73) Assignee: Samsung Electro-Mechanics Co., Ltd., Suwon-si (KR)

(21) Appl. No.: 15/373,206

(22) Filed: Dec. 8, 2016

(30) Foreign Application Priority Data
Feb. 22, 2016 (KR) 10-2016-0020384

(51) Int. Cl. H01L 23/552; H01L 23/00; H01L 25/00; H01L 21/56; H01L 25/065; H01L 23/31

(52) U.S. Cl. CPC H01L 23/552; H01L 25/0655; H01L 23/3121; H01L 25/50; H01L 21/565; H01L 24/17

(57) ABSTRACT

A package module includes first and second components, a conductive wall, and a molding portion. The first component and the second component are disposed on a substrate. The conductive wall is disposed between the first component and the second component. The molding portion is disposed on the first component, the second component, and the conductive wall, and has a slot defining a cavity above an upper portion of the conductive wall.

### CROSS-REFERENCE TO RELATED APPLICATIONS

This application claims benefit under 35 USC 119(a) of Korean Patent Application No. 10-2016-0020384 filed on Feb. 22, 2016 in the Korean Intellectual Property Office, the entire disclosure of which is incorporated herein by reference for all purposes.

### BACKGROUND

1. Field

The present disclosure relates to a package module and a method of manufacturing the same.

2. Description of Related Art

Package modules have seen gradual development from unit chip package structures or function module structures to composite system-in-package (SIP) modules, and correspondingly, demand for single packages with respect to composite SIP modules has gradually increased.

However, a great deal of difficulty is required when manufacturing SIP modules due in part to the densely packed components having different electrical characteristics in close proximity with each other. This results in electromagnetic interference (EMI) occurring between such densely disposed components that degrades the performance of the components.

Therefore, it is highly desirable to reduce EMI occurring within a single package.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a package module includes first and second components, a conductive wall, and a molding portion. The first component and the second component are disposed on a substrate. The conductive wall is disposed between the first component and the second component. The molding portion is disposed on the first component, the second component, and the conductive wall, and has a slot defining a cavity above an upper portion of the conductive wall.

The cavity may expose an upper surface of the conductive wall.

The cavity may have a V profile.

The conductive wall may have a conic profile.

An upper surface of the conductive wall may be narrower than an upper portion of the cavity.

An inner wall surface of the molding portion defining the cavity may have a stepped shape.

An inner wall surface of the molding portion defining the cavity may be inclined with respect to the conductive wall.

The package module may further include a conductive layer disposed on the molding portion and the conductive wall.

In another general aspect, a method of manufacturing a package module includes disposing a first component and a second component on a substrate; forming a conductive wall between the first component and the second component; forming a molding portion to cover portions of the first component, the second component, and the conductive wall; and forming a cavity above a region of the molding portion disposed on the conductive wall.

The cavity may be formed to expose an upper portion of the conductive wall.

The cavity may have a V profile.

The conductive wall may have a conic profile.

An inner wall surface of the molding portion defining the cavity may be inclined with respect to the conductive wall.

The package module may further include forming a conductive layer disposed on the molding portion.

In another general aspect, a package module includes components, a conductive wall, a molding material, and a conductive layer. The components are disposed on a substrate. The conductive wall is disposed between a first component and a second component. The molding material is disposed on portions of the components and the conductive wall. The conductive layer is disposed on the molding material. The conductive layer above the conductive wall is contiguous with an upper surface of the conductive wall to form an electromagnetic interference shield.

A cavity may be formed in the molding material to expose the upper surface of the conductive wall before the conductive layer is disposed on the molding material.

The cavity may have a V profile.

The cavity may have a stepped V profile.

The conductive wall may have a conic profile.

According to an exemplary embodiment in the present disclosure, a package module may include a conductive wall disposed between a first component and a second component disposed on a substrate, and a molding portion covering the first component, the second component, and the conductive wall, and having a slot structure in which a cavity is provided above the conductive wall. Electromagnetic waves between components having the same or different electrical characteristics may be blocked, and a design of a conductive layer may be facilitated.

Other features and aspects will be apparent from the following detailed description, the drawings, and the claims.

### BRIEF DESCRIPTION OF DRAWINGS

FIG. 1 is a perspective plan view of an example of a package module according to an embodiment.

FIG. 2 is a schematic cross-sectional view of an example of a package module according to an embodiment.

FIG. 3 is an enlarged view of portion A of FIG. 2 illustrating a shape of the cavity of a package module according to an embodiment.

FIG. 4 is an enlarged view of portion A of FIG. 2 illustrating a shape of the cavity of a package module according to an embodiment.

FIG. 5 is a method of manufacturing a package module according to an embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

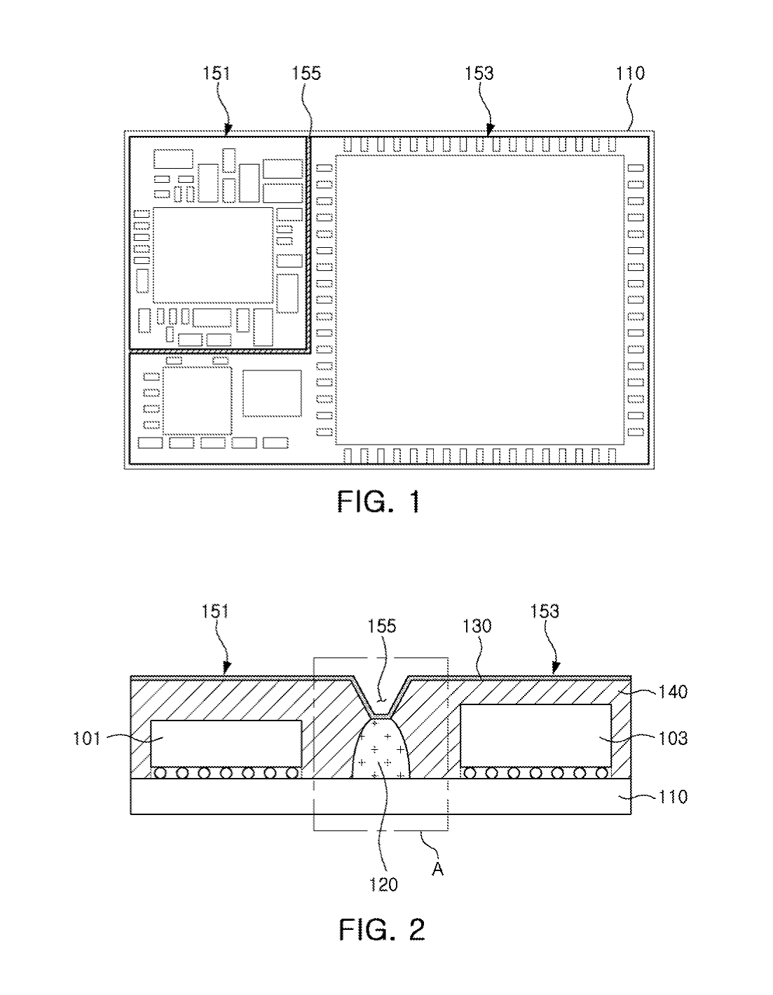

FIGS. 1 and 2 respectively depict schematic plan view and a cross-sectional view of a package module 100 according to an embodiment.

With reference to FIGS. 1 and 2, a package module 100 according to an embodiment includes first component 101 and second component 103 disposed on a substrate 110, a conductive wall 120 disposed between the first component 101 and the second component 103, and a molding portion 140. The molding portion 140 covers portions of the first component 101, the second component 103 and the conductive wall 120. A slot defining a cavity 155 is formed above the conductive wall 120.

The substrate 110 may be formed using an insulating ceramic material.

The substrate 110 may be a single alumina (Ai₂O₃) sintered body or an aluminum oxide sintered body in which flat ceramic green sheets are laminated.

The first component 101 and the second component 103 are electronic components having the same or different electrical characteristics; however, there is EMI generated by one or both components.

The molding portion 140 may be formed of a resin. Although not particularly limited, the resin for the molding portion 140 may be selected from an epoxy-based resin and/or a silicon-based resin.

The molding portion 140 may be formed to encase or surround portions of the first component 101 and the second component 103.

Due to the electrical characteristics of the first component 101 and the second component 103, EMI may occur between the components through electromagnetic induction, electrostatic coupling, or conduction. The disturbance (or mutual interference) may degrade the performance of the first component 101 and the second component 103 or even stop them from functioning.

In the case of a system-in-package (SIP) module implemented on a substrate, the structure is generally encased by a molding portion formed of resin. In this case, in order to block EMI in the SIP module, a conformal shield for EMI shielding is formed by coating the entirety of the package in which the molding portion is formed with a conductive material to block EMI.

However, EMI shielding the entire surface of the package does not resolve EMI disturbances between components within the package.

In a package module according to an embodiment, the conductive wall 120 is disposed between the first component 102 and the second component 103.

With reference to FIGS. 1 and 2, a first region 151 in which the first component 101 is disposed, and a second region 153 in which the second component 103 is disposed are provided on the substrate 110. The first region 151 and the second region 153 are regions in which components performing different functions and/or having different electrical characteristics are disposed.

The conductive wall 120 shields interference between components of respective functional regions in the package.

The conductive wall 120 includes a conductive material that may be gold (Au), silver (Ag), nickel (Ni), tungsten (W), copper (Cu), tin (Sn), molybdenum (Mo), or alloys thereof, but is not limited thereto.

The conductive wall 120 is disposed between the bottom of the cavity 155 and the substrate 110. The conductive wall 120 has a tubular shape with a dome-shaped cross section in which the top portion closest and/or abutting the bottom of the cavity 155 has a narrower surface than the bottom portion of the conductive wall 120 abutting the substrate 110.

In this case, at the design stage, since the conductive wall 120 may be designed to have a relatively narrow width, the degree of design freedom may be increased without increasing package costs. However, the shape of the conductive wall 120 is not limited to the illustrated example. In another embodiment, the conductive wall 120 may have a tapered cross-sectional shape, a polygonal cross-sectional shape, a trapezoidal shape, or other suitable shapes.

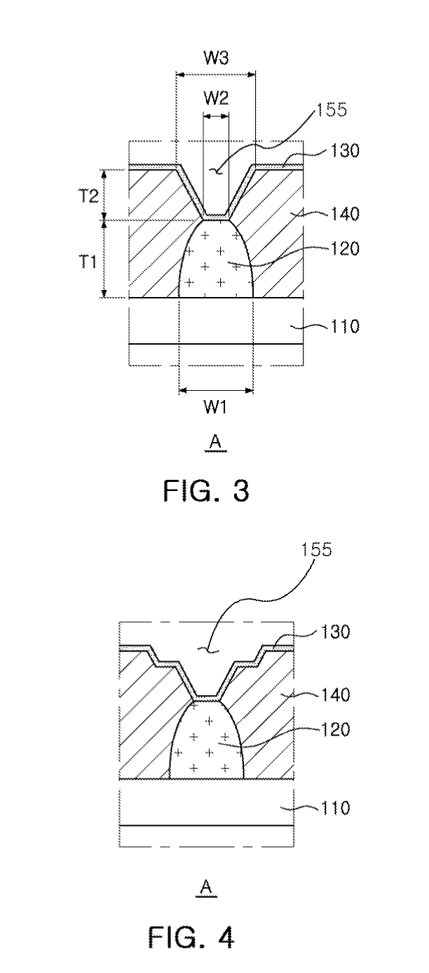

FIGS. 3 and 4 are enlarged views of portion A of FIG. 2. The figures schematically illustrate different shapes of the cavity 155 depicted in FIG. 2.

The package module 100 has a slot defining a cavity 155 formed above the conductive wall 120 in the molding portion 140.

The cavity 155 has a shape in which a region close to the conductive wall 120 is relatively narrow.

As illustrated in FIGS. 3 and 4, the contour of the molding portion 140, forming the cavity 155, is inclined with respect to the conductive wall 120. In FIG. 3, the contour of the molding portion 140 forms a V profiled cavity 155 while having an overall tapered V shape or an upside down trapezoidal shape. In FIG. 4, the contour of the molding portion 140 forming the cavity 155 is stepped.

The first component 101 and the second component 103 may have different sizes. In this case, inclinations of respective inner wall surfaces of the molding portion 140 toward the cavity 155 may be different from each other.

When the cavity 155 is formed, since the cavity is formed to have a V profile, the upper surface of the conductive wall 120 may be narrower than an upper portion of the cavity 155.

For example, when a height of the molding portion 140 is 1, the height of the conductive wall 120 may be in a range of 0.3 to 0.5, and the depth of the cavity 155 may be in a range of 0.5 to 0.7. Due to the disposition of the conductive wall 120, the cavity 155 may not have a height corresponding to a height of the molding portion 140, and the occurrence of defects in the substrate 110 due to physical collisions thereto may be prevented. Shielding effects may be secured.

In a case in which the cavity is formed to have a relatively deep depth, at the time of forming a conductive layer, a portion of the conductive layer may not be formed to a lower surface of the cavity. Thus, shielding effects may not be secured.

In a case in which a height of the cavity should be formed more deeply, such a problem as described above may be solved by differentiating an upper width of the cavity from a width of an upper surface of the conductive wall 120. For example, an inclination of an inner wall surface of the cavity is slow by increasing the upper width of the cavity, in such a manner that the conductive layer is formed on a lower surface of the cavity.

When the conductive layer is formed, a formation angle of the cavity is adjusted in phases to be suitable for process capabilities, and thus, a conductive formation process may be easily performed.

In a case in which a surface of the conductive wall 120 close to a substrate 110 refers to a lower surface thereof, and a surface thereof opposed thereto refers to an upper surface of the conductive wall 120, when a width of an upper surface of the conductive wall 120 is 1, a width of a lower surface of the conductive wall 120 is in a range of 0.8 to 1.2, and a width of an upper portion of the cavity 155 is in a range of 1.2 to 1.6. For example, the upper portion of the cavity 155 has a width greater than that of a lower surface of the conductive wall 120.

A conductive layer 130 is disposed on the molding portion 140.

The conductive layer 130 may be formed on an inner wall surface of the cavity 155.

The conductive layer 130 and the conductive wall 120 may be formed of a conductive material such as gold (Au), silver (Ag), nickel (Ni), tungsten (W), copper (Cu), tin (Sn), molybdenum (Mo), and alloys thereof, but is not limited thereto.

When the cavity 155 is formed, the cavity 155 is formed exposing an upper portion of the conductive wall 120. The conductive layer 130 is then formed on the upper portion of the conductive wall 120. Thus, the conductive layer 130 is contiguously formed on an upper surface of the conductive wall 120 to form a shield wall.

Thus, in the package module 100 according to the embodiments, in order to block electromagnetic wave interference externally generated and/or cross-coupled between the first component 101 and the second component 103 in the first region 151 and the second region 153, the conductive wall 120 and the conductive layer 130 disposed in the cavity 155 on the conductive wall 120 are provided. Thus, EMI generated externally and/or between the first region 151 and the second region 153 can be mitigated against.

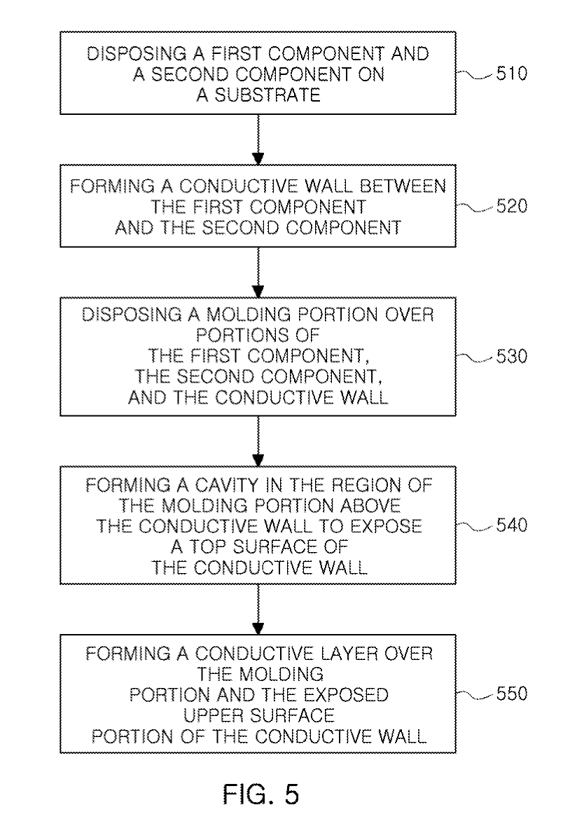

Hereinafter, a method of manufacturing a package module according to an embodiment illustrated in FIG. 5 will be described.

According to FIG. 5, a method of manufacturing a package module 100 includes disposing a first component 101 and a second component 103 on a substrate 110 in 510. A conductive wall 120 is formed between the first component 101 and the second component 103 in 520. A molding portion 140 is disposed over portions of the first component 101, the second component 103, and the conductive wall 120 in 530. A cavity 155 is formed in the region of the molding portion 140 above the conductive wall 120 to expose a top surface of the conductive wall 120 in 540.

The substrate 110 may be formed of an insulating ceramic material, and may be an alumina (Ai2O3) sintered body in which ceramic green sheets are laminated or a single alumina sintered body.

The first component 101 and the second component 103 may have the same or different electrical characteristics; however, there is EMI generated by one or both components.

The conductive wall 120 is disposed to block or mitigate the EMI between the first component 101 and the second component 103.

The conductive wall 120 includes conductive material, or may be formed using a metal frame or a metal paste. Examples of the conductive material include gold (Au), silver (Ag), nickel (Ni), tungsten (W), copper (Cu), tin (Sn), molybdenum (Mo), and alloys thereof, but the conductive material is not limited thereto.

The conductive wall 120 has a conic profile where the region abutting the substrate 110 is relatively wide.

Next, after forming the molding portion 140 a cavity 155 is formed above a region of the molding portion 140 in which the conductive wall 120 has been formed.

The molding portion 140 may be formed of a resin. Although not particularly limited, the resin may be one selected from an epoxy-based resin and a silicon-based resin.

A cavity 155 is formed in the region of the molding portion 140 above the conductive wall 120 to expose a top surface of the conductive wall 120.

The cavity 155 is formed using a method such as a laser drilling method, a mechanical drilling method, or the like.

The cavity 155 has a V contour in which the bottom region of the cavity 155 close to the conductive wall 120 is relatively narrow. In detail, an inner wall surface of the contour of the cavity 155 is inclined with respect to the conductive wall 120. A conductive layer 130 is then formed over the molding portion 140 and the exposed upper surface portion of the conductive wall 120 in 550.

During formation of the cavity 155, by controlling the inclination of the inner wall surface in phases, the width and the depth of the cavity 155 may be adjusted to allow for easy formation of the conductive layer in a post process.

For example, when a thickness of the molding portion 140 is relatively thick at the time of forming the cavity 155, the cavity 155 formed on an upper surface of the conductive wall 120 will not induce warpage in the package module 100. Thus, the process of forming the cavity 155 may be easily performed to avoid the occurrence of defects due to external stress in manufacturing the package module 100.

In addition, when the cavity 155 is formed in an upper portion of the molding portion 140, reliability of the molding portion 140 formed of a resin may be improved and warpage may also be prevented through a thermal expansion coefficient.

Then, the conductive layer is formed on the molding portion 140 and an upper surface of the conductive wall 120.

The conductive layer may be formed of a conductive material. Although not particularly limited, the conductive layer may be formed using a method such as a sputtering method, a chemical vapor deposition (CVD) method, or the like.

As the conductive wall 120 and the conductive layer 130 formed on an upper surface of the conductive wall 120 are formed to be connected to each other, an EMI shield wall is formed.

The described examples allow for the height of the conductive wall 140 to be reduced, since the cavity 155 is formed above the conductive wall 120 in the molding portion 140. At the design stage, since the conductive wall may be designed to have a relatively narrow width, a degree of design freedom is increased without increasing package costs.

Further the inclined wall of cavity 155 allows for the conductive layer 130 to be more easily formed. If the cavity 155 has a vertical wall, forming the conductive layer on the vertical wall by a sputtering method or a chemical vapor deposition (CVD) will be difficult.

As set forth above, in a package module according to embodiments, electromagnetic interference occurring between components having different electrical characteristics may be blocked, and a conductive layer may be easily designed without increasing package costs.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A package module, comprising:
a first component and a second component disposed on a substrate;
a conductive wall disposed between the first component and the second component; and
a molding portion disposed on portions of the first component, the second component, and the conductive wall, and having a slot defining a cavity above an upper portion of the conductive wall.

2. The package module of claim 1, wherein the cavity exposes an upper surface of the conductive wall.

3. The package module of claim 1, wherein the cavity has a V-shaped cross section.

4. The package module of claim 1, wherein the conductive wall has an elongated tubular shape with a dome-shaped cross-section.

5. The package module of claim 1, wherein an upper surface of the conductive wall is narrower than an upper portion of the cavity.

6. The package module of claim 1, wherein an inner wall surface of the molding portion defining the cavity has a stepped profile.

7. The package module of claim 1, wherein an inner wall surface of the molding portion defining the cavity is inclined with respect to the conductive wall.

8. The package module of claim 1, further comprising a conductive layer disposed on the molding portion and the conductive wall.

9. A method of manufacturing a package module, comprising:
disposing a first component and a second component on a substrate;
forming a conductive wall between the first component and the second component;
forming a molding portion to cover portions of the first component, the second component, and the conductive wall; and
forming a cavity above a region of the molding portion disposed on the conductive wall.

10. The method of claim 9, wherein the cavity is formed expose an upper portion of the conductive wall.

11. The method of claim 9, wherein the cavity has a V-shaped cross section.

12. The method of claim 9, wherein the conductive wall has an elongated tubular shape with a dome-shaped cross-section.

13. The method of claim 9, wherein an inner wall surface of the molding portion defining the cavity is inclined with respect to the conductive wall.

14. The package module of claim 9, further comprising forming a conductive layer disposed on the molding portion.

15. A package module, comprising:
a conductive wall disposed on a substrate between two or more components;
a molding material disposed on the components and the conductive wall; and
a conductive layer disposed on the molding material, wherein the conductive layer above the conductive wall is contiguous with an upper surface of the conductive wall to form an electromagnetic interference shield.

16. The package module of claim 15, wherein a cavity defined by side surfaces of the molding material and the upper surface of the conductive wall.

17. The package module of claim 16, wherein the cavity forms a slot above the conductive wall, and has a V-shaped cross section.

18. The package module of claim 16, wherein the cavity has a stepped V-shaped cross.

19. The package module of claim 15, wherein the conductive wall has an elongated tubular shape with a dome-shaped cross-section.
